(19) United States
(12) Patent Application Publication
(10) Pub. No.: US 2012/0229128 A1
(43) Pub. Date: Sep. 13, 2012

(54) Magnetic Field Sensor

(76) Inventor: Armin SATZ, Villach (AT)

(21) Appl. No.: 13/044,582

(22) Filed: Mar. 10, 2011

(51) Int. Cl. G01R 33/02

(52) U.S. Cl. 324/244

(57) ABSTRACT

Embodiments related to magnetic field sensors are described and depicted.

### BACKGROUND

Magnetic field sensors are nowadays used in many applications for determining a magnitude of a magnetic field, an angle of a magnetic field or other properties related to magnetic fields. Examples of such applications include current sensors which measure an electrical current by the magnetic field generated by the current, angular sensors for sensing an angle of a rotatable magnetic field such as a magnetic field generated by a rotatable element, or a speed sensor for determining a rotational or other speed of an element by measuring the magnetic field. For measuring magnetic fields, various types of sensors are known. Besides Hall sensors, XMR sensors are becoming more and more important for measuring magnetic fields. XMR sensors are magnetoresistive sensors which are based on a magnetoresistive effect where the “X” stands as a placeholder for the various types of magnetoresistive effects. XMR sensors include for example GMR sensors (GMR=giant magnetoresistance), AMR sensors (AMR=anisotropic magnetoresistance) CMR sensors (CMR=colossal magnetoresitance) and TMR (TMR=Tunnel magnetoresistance).

### BRIEF DESCRIPTION OF THE SEVERAL VIEWS OF THE DRAWINGS

FIG. 1 shows a block diagram according to an embodiment;

FIGS. 2A, 2B and 2C shows exemple diagrams illustrating the operation of XMR sensors;

FIGS. 3A and 3B show examples illustrating magnetic vectors according to an embodiment;

FIGS. 4A and 4B show diagrams according to an embodiment with multiple XMR elements; and

FIG. 5 shows a flow chart diagram according to an embodiment.

### DETAILED DESCRIPTION

The following detailed description explains exemplary embodiments of the present invention. The description is not to be taken in a limiting sense, but is made only for the purpose of illustrating the general principles of embodiments while the scope of protection is only determined by the appended claims.

In the exemplary embodiments shown in the drawings and described below, any direct connection or coupling between functional blocks, devices, components or other physical or functional units shown in the drawings or described herein can also be implemented by an indirect connection or coupling. Functional blocks may be implemented in hardware, firmware, software, or a combination thereof.

Further, it is to be understood that the features of the various exemplary embodiments described herein may be combined with each other, unless specifically noted otherwise.

In the various figures, identical or similar entities, modules, devices etc. may have assigned the same reference number.

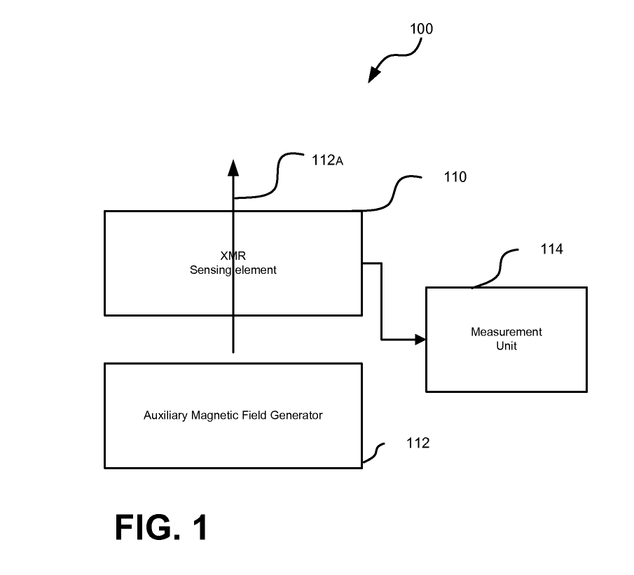

Referring now to FIG. 1, a block diagram of an example magnetic field sensor 100 for measuring at least one property of a measurement magnetic field is shown. The measurement magnetic field measured by the magnetic field sensor 100 may typically be an external magnetic field such as for example a magnetic field caused by a movement or rotation of an object. In some embodiments, the measurement magnetic field may for example include a magnetic field which depends on and allows to determine a specific position or rotation angle of an element. In some embodiments, the magnetic field sensor 100 may for example be an angular sensor capable of measuring a rotational or spatial direction of a magnetic field which allows indentifying a rotational angle of the element or a speed sensor for measuring a rotational speed of an element. However, the magnetic field sensor 100 is not limited to the above described types.

The magnetic field sensor 100 comprises a XMR sensing element 110 for sensing a magnetic field. The XMR sensing element 110 may be of any known XMR type including but not limited to GMR (Giant magnetoresistance), AMR (Anisotropic magnetoresistance), CMR (Colossal magnetoresistance), TMR (Tunneling magnetoresistance) etc. The XMR sensing element 110 may include for example a single XMR stripe, multiple XMR stripes which may for example be arranged in a specific configuration such as a Wheatstone bridge configuration or other types or configurations used for sensing magnetic fields. The XMR sensing element 110 is configured to sense a magnetic field present at the XMR sensing element 110 by a change of an electrical resistance. Depending on the specific configuration, the XMR sensing element 110 may typically sense the magnetic field by providing an output voltage or an output current indicative of at least one property of the magnetic field present at the XMR sensing element 110.

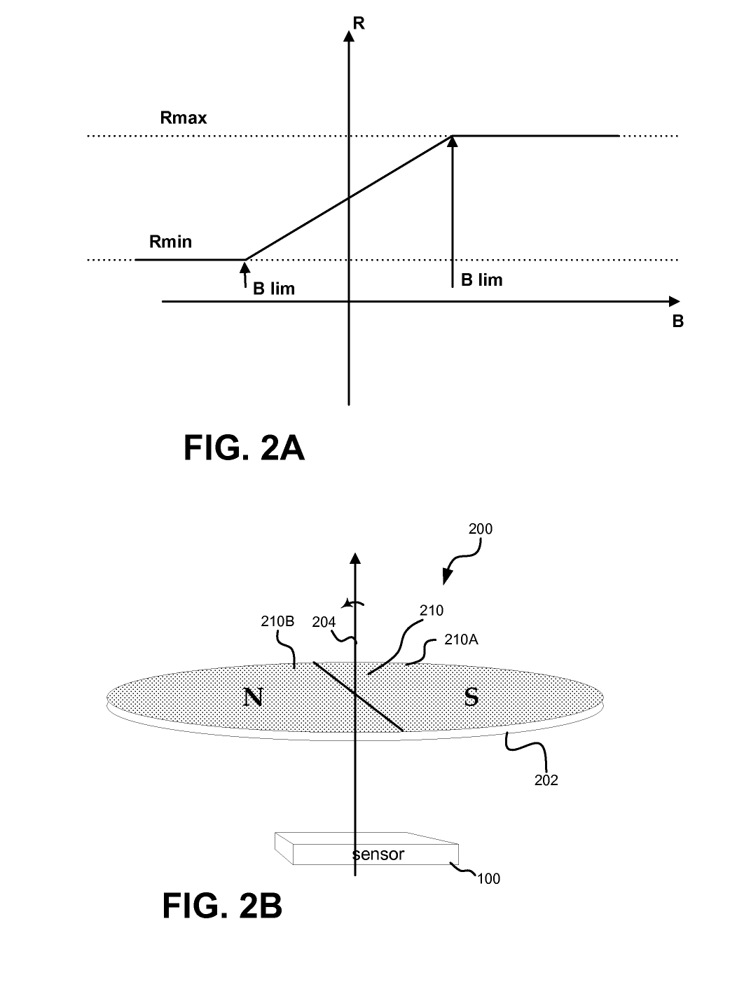

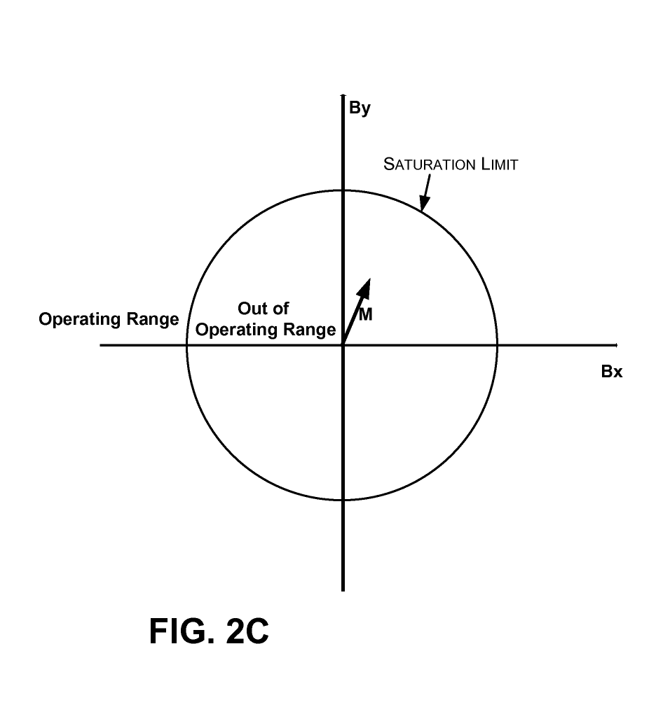

FIG. 2A shows a typical resistance characteristic of a GMR sensing element as a function of a magnetic field.

As can be seen from FIG. 2A, for magnetic fields having a magnitude higher than a saturation limit Bₗᵢₘ, the resistance experiences saturation. In the saturation region, the resistance is either at the lowest value Rmin or at the highest value Rmax depending on the direction of the magnetic field and approximately remains at the respective saturation level.

For sensing magnetic fields, XMR sensing elements include a magnetic layer comprising magnetizable material. When sensing a magnetic field, the magnetizable material is magnetized in the direction of the external measurement magnetic field. In other words, the magnetization of the magnetic layer follows the magnetization of the external measurement field. The angle of this magnetization of the magnet layer determines the resistance of the XMR sensor element which allows using the XMR element as sensor.

While strong magnetic fields forces a full magnetization of the magnetic layer in the direction of the external magnetic field, for weak magnetic fields only parts or domains of the magnetic layer are magnetized in the direction of the measurement field while other parts or domains may still have magnetizations in other directions. As the resistance of the XMR sensing elements depends on the angle of the magnetization within the magnetic layer, it is to be understood that for weak measurement magnetic fields a further increase of the magnitude of the measurement magnetic field results in more domains being aligned in the same direction and therefore the resistance changes. In the saturation regime, the measurement magnetic field is strong enough to cause the magnetic layer fully magnetized and therefore any further increase of the magnetic field does not cause any further change in the resistance.

For many applications of XMR sensors such as for example in angle or rotational sensing applications it is desired to operate the XMR sensing element in saturation, i.e. to have the magnitude of the measurement magnetic field vector exceeding the saturation limit. The measurement magnetic field is the magnetic field for which at least one property such as an angle or rotational speed is to be determined by the XMR sensor. In applications like speed sensor or angle sensors, the measurement magnetic field is typically linked to a rotatable object. FIG. 2B shows an example of an angle sensor 200. A magnet 210 having a south pole 210A and a north pole 210B is mounted on an object 202 arranged to be rotatable around an axis 204. The magnetic field sensor 100 is provided to sense an angle of the object 202 by measuring an angle of the measurement magnetic field generated by the magnetic 202.

However, if the vector of the measurement magnetic field M is below the saturation limit, the XMR sensing elements can be considered out of the operating range as indicated in FIG. 2C.

Embodiments as described herein provide a new concept to address the measuring of at least one property of magnetic fields such as for example an angle or rotational speed of the measurement magnetic field when the magnitude of the measurement field is low such as below the saturation limit. The new concept utilizes an auxiliary magnetic field which is generated in order to have at the location of the XMR sensing element a composite magnetic vector as a result of the vector addition of the measurement magnetic vector and the auxiliary magnetic vector. In embodiments, the magnitude of the resulting composite magnetic vector exceeds the saturation limit during at least a sensing phase which allows the magnetic field sensor to sense the composite magnetic vector to sense the composite magnetic vector above the saturation limit. Based on the information of the sensed composite magnetic vector and the properties of the auxiliary magnetic field, at least one property of the measurement magnetic field can be derived.

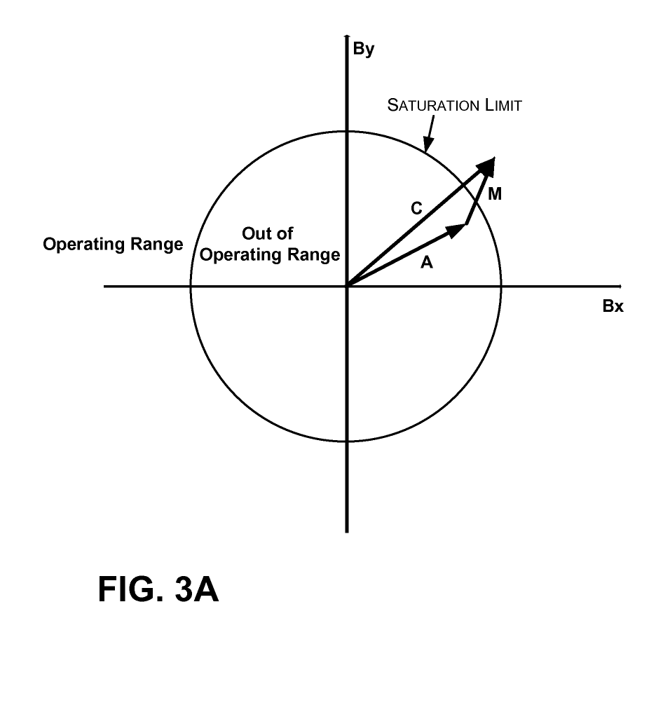

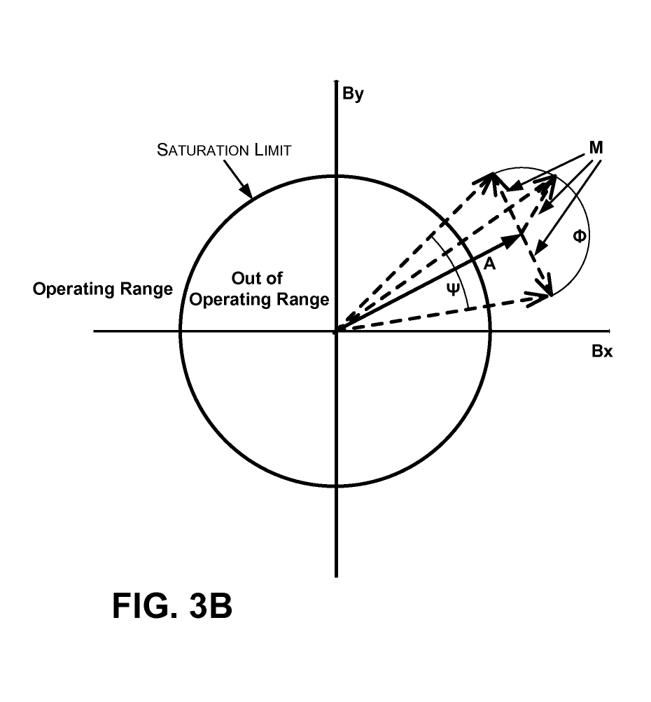

FIG. 3A shows a diagram illustrating an example of the new concept in which an auxiliary magnetic field vector A is added by way of vector addition to the measurement magnetic vector M to obtain a resulting composite magnetic vector C. In FIG. 3A, by adding the auxiliary magnetic field vector, the magnitude of the composite magnetic vector C is above the saturation limit which allows sensing the composite vector C in the saturation limit of the XMR sensing element.

It may be realized that the auxiliary magnetic field 112A can be regarded as a modulation magnetic field such that the measurement magnetic field is modulated onto the auxiliary magnetic field in order to establish a magnetic field which exceeds the saturation limit of the XMR sensing element and which is sensed by the XMR sensing element.

Referring now again to FIG. 1, an auxiliary magnetic field generator 112 is provided in order to generate an auxiliary field 112A as described above.

By implementing the auxiliary magnetic field 112a, the magnetic field sensor 100 is capable of measuring properties of measurement magnetic fields which are smaller than a saturation limit of the XMR sensing. It is to be noted here that the provision of the auxiliary magnetic field 112a is not for making the XMR sensing element in general functional for magnetic field measurements. In other words, the XMR sensing element without the auxiliary magnetic field may be a fully functional sensing element. However, the auxiliary magnetic field 112A adds to the measurement magnetic field to provide at the XMR sensing element 112 a resulting composite magnetic field vector which exceeds the saturation limit of the XMR sensing element 112 in order to enable for small measurement fields a measurement with full saturation of the variable magnetic layer.

The magnetic field generator 112 may in some embodiments include a generator capable of generating magnetic fields which are variable in magnitude and/or direction. An example of such a magnetic field generator may for example include a coil. The electric current flowing through the coil may be controlled by a controller in order to generate the auxiliary magnetic field 112A at least during a sensing phase with a predefined magnitude and direction such that the sensed resulting composite magnetic vector exceeds the saturation limit of the XMR sensing element.

In some embodiments, the auxiliary magnetic field generator 112 permanently generates the magnetic field. In such embodiments, the auxiliary magnetic field generator 112 may for example include a permanent magnet with permanently magnetized material for generating the auxiliary magnetic field. However, the auxiliary magnetic field may in some embodiments be generated permanently in other ways for example by a permanent current flowing through a coil etc.

In some embodiments, the auxiliary magnetic field is generated only locally at the location of the XMR sensing element. In some embodiments, magnetic flux shaping elements may be used to shape the auxiliary magnetic field for example to locally concentrate the field at the location of the XMR sensing element 110.

In some embodiments, the generated auxiliary magnetic field 112A has at the location of the XMR sensing element 110 a magnitude equal to or higher than a saturation limit of the XMR sensing element 110. In some embodiments, the generated auxiliary magnetic field 112A may have at the location of the XMR sensing element 110 a magnitude slightly smaller or higher than the saturation limit of the XMR sensing element 110. The saturation limit is depending on the material and type of the XMR sensors. Typically the saturation limit is in the range between 0.5 mTesla and 5 mTesla. Therefore, in some embodiments, the generated auxiliary magnetic field 112A may have at the location of the XMR sensing element 110 a magnitude in the range between 0.5 mTesla and 20 mTesla. In some embodiments, the generated auxiliary magnetic field 112A may have at the location of the XMR sensing element 110 a magnitude in the range between 0.5 mTesla and 5 mTesla. It is to be noted that the auxiliary magnetic field generator 112 may be integrated in a same package as the XMR sensing element 110 or may be provided external. In some embodiments, the auxiliary magnetic field generator 112 may be integrated on a same chip as the XMR sensing element.

In order to extract information regarding the one or more properties of the measurement magnetic field, the sensed output signal from the XMR sensing element 110 may be transferred to a measurement unit 114 as outlined in FIG. 1. The measurement unit 114 may either be integrated on the same device as the sensor element 110 or may be external. The measurement unit 114 may be purely hardware implemented for example implemented as a state-machine, or purely software or firmware implemented or a combination thereof.

The measurement unit 114 determines at least one property of the measurement magnetic field based on the output signal of the XMR sensing element 110. In some embodiments, the determined property of the measurement magnetic field may be an angle position of a rotatable magnetic field which is based on an angle position of a rotatable object. In some embodiments, the determined property may be a rotational speed of a rotatable magnetic field.

In order to determine the at least one property of the measurement magnetic field, some embodiments use information related to a contribution of the generated auxiliary magnetic field to an output signal of the XMR sensing element 110 in order to calculate the at least one property of the measuring magnetic field based on the output signal. Such information may for example include information related to the magnitude and direction of the auxiliary magnetic field. The contribution of the auxiliary magnetic field vector at the location of the XMR sensing element may then be taken into account when analyzing the output signal of the XMR sensing element and determining the at least one property of the measurement magnetic field. The property of the measurement magnetic field is hereby determined based on information regarding the influence which the added auxiliary magnet field vector has on the output signal of the XMR sensing element, i.e. the modification of the XMR sensing element output signal caused by the presence of the auxiliary magnetic field. The at least one property of the measurement magnetic field may for example be determined by a calculation corresponding to the subtraction of the auxiliary magnetic field vector. Furthermore such information may for example include mapping information obtained and stored during a training, calibration or testing of the magnetic field sensor.

The mapping information may for example include values which are based on the observing and storing of output signal values of the XMR sensing element 110 obtained during training, calibration or testing when a reference measurement magnetic field is applied. A mapping of the output signals to the respective values of the applied reference measurement magnetic field may be applied and stored. The mapping information may indicate a mapping of the output signal information from the XMR sensing element 110 to values of at least one property of the measurement magnetic field. For example, the mapping information may include a mapping of the output signal information of the XMR sensing element to values of an angle of the magnetic field or directly to an angle of the object causing the magnetic field. The mapping information may be utilized by using statistical or other methods or algorithms such as interpolation or extrapolation techniques in order to determine a value for the at least one property of the measurement magnetic field.

FIG. 3B indicates an example to show a mapping of an angle Ψ of the sensed composite magnetic field C to an angle Φ of a measurement magnetic field M. It is to be noted that in the embodiment of FIG. 3B, the measurement is assumed to have a same magnitude for the different angles Φ. It can be seen from FIG. 3B that between 0 and 180 degree, each angle Φ of a measurement magnetic field M corresponds to a specific angle Ψ of the sensed composite magnetic field C.

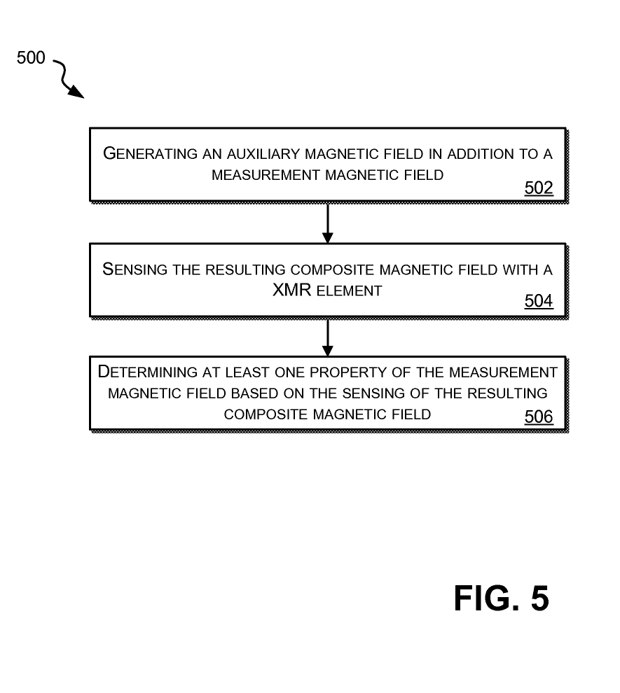

FIG. 5 shows an example of a flow chart 500 for measuring at least one property of the measurement magnetic field. The flow chart starts at 502 by generating an auxiliary magnetic field in addition to a measurement magnetic field. At 504, the resulting composite magnetic field is sensed by using the XMR element. At 506, at least one property of the measurement magnetic field is determined based on the sensing of the resulting composite magnetic field.

In some embodiments, the measurement unit 114 may also provide an indication or determination whether the magnitude of the measurement signal is lower than the saturation limit.

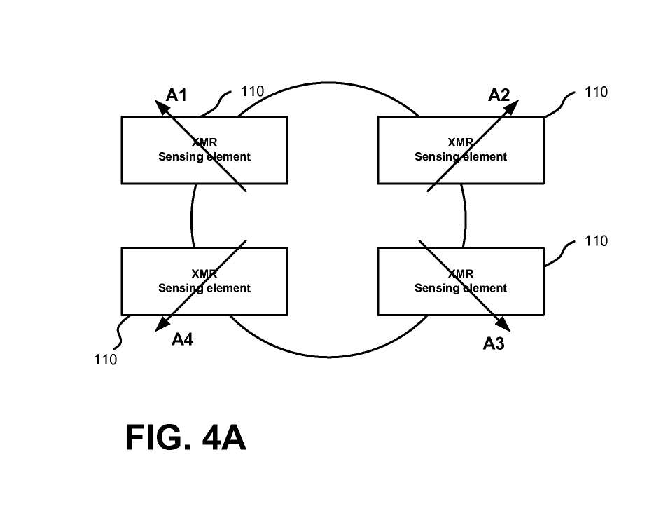

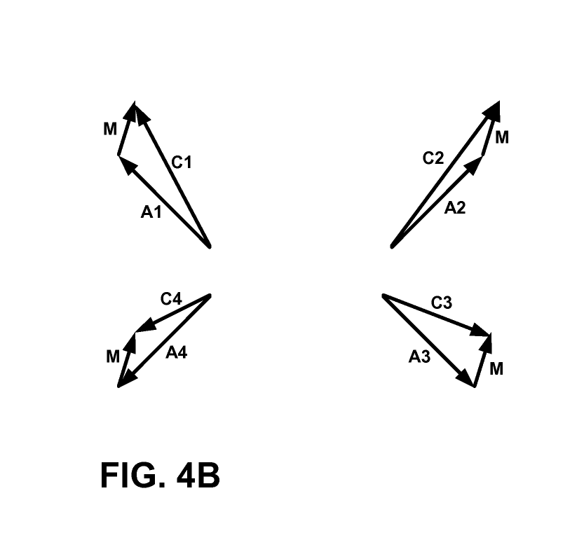

Referring now to FIG. 4A, an example embodiment of a magnetic field sensor is shown which has more than one XMR sensing element provided to determine a property of the measurement magnetic field.

Although having increased area, the utilization of more than one XMR sensing element may for some embodiments be advantageous for example to ensure that at least one of the XMR sensing elements has for each possible measurement magnetic field a composite magnetic field above the saturation limit.

While FIG. 4A shows an embodiment with four XMR sensing elements 110, it is to be noted that any other plurality of XMR sensing elements such as for example two, three, five or more may be implemented in other embodiments.

In the embodiment of FIG. 4A, the four XMR sensing elements 110 are distributed along a circle. However any other symmetrical or asymmetrical arrangement or distribution of XMR sensing elements 112 may be included in other embodiments.

Furthermore, each of the XMR sensing elements 112 has a corresponding auxiliary magnetic field with each direction different to the other directions. In the embodiment shown in FIG. 4A, the magnitude of each auxiliary magnetic field at the location of the corresponding XMR sensing element 112 is the same. However other embodiments may include varying magnitudes.

In the embodiment of FIG. 4A, the four auxiliary magnetic field vectors are arranged symmetrical, i.e. in directions corresponding to 360°/n with n=4. However, other embodiments may have non-symmetrical arrangement of the auxiliary magnetic field vectors.

FIG. 4B shows how the multiple auxiliary magnetic field vectors A1 to A4 add to a vector of the measurement field M. As can be seen, with the auxiliary magnetic fields A1 to A4 being fixed or predetermined, the resulting directions of the composite magnetic field vectors C1 to C4 provide a characteristic angle distribution for each measurement magnetic field vector M. Therefore, when each of the XMR sensing elements 110 provides in the output signal information with respect to a measured angle of the corresponding composite magnetic field vectors C1 to C4, the angle and/or magnitude of the measurement magnetic field vector M can be determined from the measured distribution of the angles of the composite magnetic field vectors C1 to C4. In order to determine the mapping of measured angle distributions of the vectors C1 to C4 to an angle and/or magnitude of the measurement magnetic field M, various methods may be used. For example, during a testing or calibration, predetermined measurement magnetic fields may be applied to determine for each applied measurement magnetic field the corresponding angle distribution of the composite vectors C1 to C4. This data may be stored for example in lookup tables. The stored data may then be utilized during operation to determine for an unknown measurement magnetic field the angle and/or magnitude. Only as an example, statistical tools such as interpolation, extrapolation, least square means etc. may be used to determine an angle and/or magnitude of the measurement magnetic field from the stored data and the output signals of the XMR sensing elements which are based on a measurement of the composite magnetic fields C1-C4 at the corresponding XMR sensing elements.

Furthermore, in some embodiments the value of the auxiliary fields A1 to A4 at the locations of the XMR sensing elements 110 may be determined prior to starting the operation of the sensor. This may for example be obtained by measuring each of the auxiliary fields during a calibration, testing or other process prior to the operation of the sensor. Based on this information, the magnitude and/or angle of an unknown measuring magnetic field M may be determined during operation of the sensor. Mathematically, this may be derived for example from solving equations which can be established in view of the relationship of the vectors of M, A1-A4 and the composite vectors of C1-C4. For each XMR sensing element i, the following equations can be obtained, wherein Mx is an x-axis component of the measurement magnetic field, Ax,i is an x-axis component of the auxiliary magnetic field, My is a y-axis component of the measurement magnetic field, Ay,i is an y-axis component of the auxiliary magnetic field, θi is an angle of the auxiliary magnetic fields Ai, and Ψi is an angle of the composite magnetic field Ci:

Tan θi=Ay,i/Ax,i

Tan Ψ=My/Mx

Cx=Mx+Ax,i

Cy=My+Ay,i

Persons skilled in the art will realize that by having established the above equation for each XMR sensing element i, the angle Ψ of the measurement magnetic field M may be easily determined based on the sensed angles θi which corresponds to the output signal of the respective XMR sensing element i.

It may be realized that the above described concept can be implemented at low costs. There is no need for changing an existing design of an XMR sensing element itself as long as the XMR sensing element is capable of sensing an angle of a magnetic field. Only the magnetic field generator is to be added and the measurement unit to be adapted or programmed to determine the magnetic measurement field in the above described manner. However, it is to be noted that the above described example is only one of many examples to derive a property of the measurement magnetic field such as an angle from the sensed composite magnetic field.

As described above, in some cases, a composite vector sensed at one of the XMR sensing elements may be lower than the saturation limit. It may be realized that with the multiple XMR sensing elements it is possible to detect whether one of the XMR sensing elements has a composite vector lower than the saturation limit. This may for example be achieved by calculating the angle Ψ not only by taking into consideration all XMR sensing elements but also in addition calculating the angle Ψ by considering only a subset of the multiple XMR sensing elements. If the determined angle Ψ is the same or substantially the same for all XMR sensing element and the subset of XMR sensing elements, all of the XMR sensing elements sense a composite magnetic vector above the saturation limit. Vice versa, if the calculated angle Ψ results in different values for the two calculations, the composite magnetic field of at least one of the XMR sensing elements is below the saturation limit. In another example, the angle Ψ may be calculated for each of the XMR sensing elements based on the determined composite magnetic vector at the respective XMR sensing element. Then the various determined values for the angle Ψ are compared. If all of the values are the same or substantially the same, the composite vector is above the saturation limit for each XMR sensing element. If one of the values substantially differs from the other values significant, the corresponding XMR sensing element is determined to having sensed a composite vector which is below the saturation limit. The corresponding value is then discarded for the measurement of the angle Ψ.

Furthermore, in some embodiment, a dynamic control of the generated auxiliary magnetic field may be utilized in order to optimize the generation of the magnetic field in view of sensitivity and power efficiency. Typically, the most sensitivity is expected when the composite magnetic is slightly above the saturation limit. Some embodiments may therefore incorporate a dynamic control wherein a control signal from the measurement unit 114 is fed back to the magnetic field generator 112 in order to adjust the auxiliary magnetic field in view of the sensed composite magnetic field.

While some of the above embodiments have been described with respect to a rotational sensing application, it is to be understood that other embodiments may include other application. In such applications, properties other than an angle of the measurement field may be sensed.

In the above description, embodiments have been shown and described herein enabling those skilled in the art in sufficient detail to practice the teachings disclosed herein. Other embodiments may be utilized and derived there from, such that structural and logical substitutions and changes may be made without departing from the scope of this disclosure.

This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

It is further to be noted that specific terms used in the description and claims may be interpreted in a very broad sense. For example, the terms “circuit” or “circuitry” used herein are to be interpreted in a sense not only including hardware but also software, firmware or any combinations thereof. The term “data” may be interpreted to include any form of representation such as an analog signal representation, a digital signal representation, a modulation onto carrier signals etc. The term “information” may in addition to any form of digital information also include other forms of representing information. The term “entity” or “unit” may in embodiments include any device, apparatus circuits, hardware, software, firmware, chips or other semiconductors as well as logical units or physical implementations. Furthermore the terms “coupled” or “connected” may be interpreted in a broad sense not only covering direct but also indirect coupling.

It is further to be noted that embodiments described in combination with specific entities may in addition to an implementation in these entity also include one or more implementations in one or more sub-entities or sub-divisions of said described entity. For example, specific embodiments described herein described herein to be implemented in a transmitter, receiver or transceiver may be implemented in subentities such as a chip or a circuit provided in such an entity.

The accompanying drawings that form a part thereof show by way of illustration, and not of limitation, specific embodiments in which the subject matter may be practiced.

In the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective steps of these methods.

Further, it is to be understood that the disclosure of multiple steps or functions disclosed in the specification or claims may not be construed as to be within the specific order. Therefore, the disclosure of multiple steps or functions will not limit these to a particular order unless such steps or functions are not interchangeable for technical reasons.

Furthermore, in some embodiments a single step may include or may be broken into multiple sub-steps. Such sub-steps may be included and part of the disclosure of this single step unless explicitly excluded.

What is claimed is:

1. A method comprising:
generating an auxiliary magnetic field in addition to a measurement magnetic field such that a resulting composite magnetic field of the auxiliary magnetic field and the measurement magnetic field exceeds at the XMR element a saturation limit of the XMR element;
sensing the resulting composite magnetic field with the XMR element;
determining at least one property of the measurement magnetic field based on the sensing of the resulting composite magnetic vector.

2. The method according to claim 1, wherein the magnitude of the measurement magnetic field is during a sensing lower than the saturation limit of the XMR element.

3. The method according to claim 1, wherein determining the at least one property of the measurement magnetic field is further based on information related to a contribution of the auxiliary magnetic field to an output signal of the XMR element.

4. The method according to claim 2, wherein determining the at least one property of the measurement magnetic field is based on an extracting the at least one property of the measurement magnetic field based on an output signal of the XMR element and a processing of the output signal of the XMR element which removes a contribution of the auxiliary magnetic field.

5. The method according to claim 1, wherein the auxiliary magnetic field is held constant at least during the sensing of the composite magnetic field.

6. The method according to claim 1, wherein a magnitude and direction of the auxiliary magnetic field is predetermined prior to the sensing.

7. The method according to claim 6, wherein the auxiliary magnetic field is a non-varying magnetic field.

8. The method according to claim 1, wherein the auxiliary magnetic field is generated by a permanent magnet or a coil.

9. The method according to claim 1, wherein the auxiliary magnetic field is a first auxiliary magnetic field, the method further comprising generating a second auxiliary magnetic field in addition to the measurement magnetic field such that a resulting second composite magnetic field of the second auxiliary magnetic field and the measurement magnetic field exceeds at a second XMR element a saturation limit of the second XMR element.

10. The method according to claim 9, wherein the second auxiliary magnetic field has a direction which is different from the direction of the first auxiliary magnetic field.

11. The method according to claim 10, further comprising n XMR elements and a generating of a corresponding auxiliary magnetic field for each of the n XMR elements, where n is an integer number greater than 2.

12. The method according to claim 1, wherein the at least one property of the measurement magnetic field is an angle of the measurement magnetic field or a rotational speed of the measurement magnetic field.

13. The method according to claim 1, wherein a magnitude of the auxiliary magnetic field is equal to or higher than the magnitude of the saturation limit.

14. The method according to claim 1, wherein a magnitude of the auxiliary magnetic field is at about the magnitude of the saturation limit.

15. A magnetic sensing device comprising:
a XMR element;
a magnetic field generator to generate an auxiliary magnetic field in addition to a measurement magnetic field such that a resulting composite magnetic field of the auxiliary magnetic field and the measurement magnetic field exceeds at the XMR element a saturation limit of the XMR element;
wherein the XMR element is configured to sense the composite magnetic field; and
a unit to determine at least one property of the measurement magnetic field based on the sensed composite magnetic field.

16. The device according to claim 15, wherein the unit is configured to determine the at least one property of the measurement magnetic field by calculating the at least one property based on an output signal of the XMR element and a property of the auxiliary magnetic field.

17. The device according to claim 16, wherein the unit is configured to determine the at least one property of the measurement magnetic field based on a subtracting of the contribution of the auxiliary magnetic field.

18. The device according to claim 17, wherein the unit is configured to provide a calculation to subtract a vector of the auxiliary magnetic field from the composite magnetic field.

19. The device according to claim 15, wherein the magnetic field generator is configured to provide the auxiliary magnetic field at least during the sensing of the composite magnetic field constant.

20. The device according to claim 15, wherein a magnitude and direction of the auxiliary magnetic field is predetermined prior to the sensing.

21. The device according to claim 20, wherein the auxiliary magnetic field is a non-varying magnetic field.

22. The device according to claim 15, wherein the auxiliary magnetic field is generated by a permanent magnet or a coil.

23. The device according to claim 15, further comprising
at least one further XMR element; and
at least one further magnetic field generator to generate at least one further auxiliary magnetic field in addition to the measurement magnetic field such that a resulting composite magnetic field of the at least one further auxiliary magnetic field and the measurement magnetic field exceeds at the at least one further XMR element a saturation limit.

24. The device according to claim 23, wherein the second auxiliary magnetic field has a direction which is different from the direction of the first auxiliary magnetic field.

25. The device according to claim 24, further comprising n XMR elements, where n is an integer number greater than 2, and at least one auxiliary magnetic field generator for generating corresponding auxiliary fields for the n XMR elements.

26. The device according to claim 15, wherein a magnitude of the auxiliary magnetic field is equal to or higher than the magnitude of the saturation limit.

27. The device according to claim 15, wherein a magnitude of the auxiliary magnetic field is about the magnitude of the saturation limit.

28. The device according to claim 15, wherein the device is capable of measuring a measurement magnetic field which is lower than the saturation limit of the XMR element.

29. A sensor for determining an angle or rotation property of a rotatable element comprising:
a magnetic field generator to generate an auxiliary magnetic field in addition to a measurement magnetic field, wherein the measurement magnetic field indicates an angle or rotation of the rotatable element;
at least one XMR element to generate a XMR detection signal; and
a calculation unit to determine the angle or rotation property based on the XMR detection signal and the auxiliary magnetic field.
